(19) United States
(12) Patent Application Publication
(10) Pub. No.: US 2023/0343612 A1
(43) Pub. Date: Oct. 26, 2023

(54) MOLDING APPARATUS FOR SEMICONDUCTOR PACKAGE AND METHOD OF MANUFACTURING SEMICONDUCTOR PACKAGE

(71) Applicant: SAMSUNG ELECTRONICS CO., LTD., Suwon-si (KR)

(72) Inventors: Minkyu Park, Suwon-si (KR); Heeju Seo, Suwon-si (KR); Weonsoon Cho, Suwon-si (KR)

(73) Assignee: SAMSUNG ELECTRONICS CO., LTD., Suwon-si (KR)

(21) Appl. No.: 18/117,869

(22) Filed: Mar. 6, 2023

(30) Foreign Application Priority Data
Apr. 26, 2022 (KR) 10-2022-0051442

(51) Int. Cl. H01L 21/67; H01L 21/56

(52) U.S. Cl. CPC H01L 21/67126; H01L 21/561; H01L 21/566

(57) ABSTRACT

A molding apparatus includes a lower mold having a seating surface on which at least one substrate is seated; an upper mold clamped with the lower mold to form a molding space; at least one substrate suction groove extending in the seating surface; a plurality of first vacuum holes extending through the lower mold to be in communication with the substrate suction groove; a plurality of second vacuum holes extending through the lower mold to be opened through the seating surface; and a release film supply mechanism configured to supply a release film having a plurality of through holes, on the seating surface of the lower mold. The release film is adhered on the seating surface by suctioning air from the second vacuum holes, and the substrate is adhered on the release film by suctioning air from the first vacuum holes through the through holes of the release film.

### CROSS REFERENCE TO RELATED APPLICATION

This application claims priority under 35 U.S.C. § 119 to Korean Patent Application No. 10-2022-0051442, filed on Apr. 26, 2022 in the Korean Intellectual Property Office, the disclosure of which is incorporated herein by reference in its entirety.

### BACKGROUND

### 1. Field

Example embodiments relate to a molding apparatus for a semiconductor package and a method of manufacturing the semiconductor package using the same. More particularly, example embodiments relate to a molding apparatus for molding semiconductor chips on a substrate and a method of manufacturing a semiconductor package using the same.

### 2. Description of Related Art

In order to manufacture a semiconductor package, a plurality of semiconductor chips individualized from a wafer may be mounted on a substrate, and then, a molding member may be formed on the substrate to protect the semiconductor chips from the external environment. In this case, since the molding member formed on a lower surface of the substrate may stick to a lower mold, the mold may be cleaned using a cleaning agent. In order to omit this cleaning process and minimize foreign substances in the lower mold, a release film may be interposed between the substrate and the lower mold, but it may be difficult to adhere the substrate on the lower mold, and the substrate may be easily bent and thus defects occur.

### SUMMARY

Example embodiments provide a molding apparatus for a semiconductor package capable of stably adhering a substrate on a release film and improving production efficiency of a resin molding product.

Example embodiments provide a method of manufacturing a semiconductor package using the same.

According to example embodiments, a molding apparatus for a semiconductor package is provided. The molding apparatus may include a lower mold including: a seating surface on which at least one substrate is configured to be seated; at least one substrate suction groove extending in at least one direction in the seating surface of the lower mold; first vacuum holes extending through the lower mold such as to be in communication with the at least one substrate suction groove and in which at least a partial vacuum is configured to be formed; and second vacuum holes extending through the lower mold such as to be opened through the seating surface and in which at least a partial vacuum is configured to be formed. The molding apparatus may further include: an upper mold positioned above the lower mold and configured to be clamped with the lower mold to form a molding space configured to mold at least one semiconductor chip on the at least one substrate; and a release film supply mechanism configured to supply a release film on the seating surface of the lower mold, the release film having through holes therein, wherein the through holes of the release film disposed on the seating surface are configured to be in communication with the at least one substrate suction groove, wherein the release film is configured to be adhered on the seating surface by suctioning air from the second vacuum holes, and wherein the at least one substrate is configured to be adhered on the release film by suctioning air from the first vacuum holes through the through holes of the release film.

According to example embodiments, a molding apparatus for a semiconductor package is provided. The molding apparatus may include: a first mold including a seating surface on which at least one substrate is configured to be seated; a second mold facing the first mold and configured to be clamped with the first mold to form a molding space configured to mold at least one semiconductor chip on the at least one substrate; a release film supply mechanism configured to supply a release film on the seating surface of the first mold in a first direction, the release film having through holes that are spaced apart in the first direction; and a first adhesion support mechanism that includes: at least one first air suction line extending in the first direction in the seating surface of the first mold; first vacuum holes extending through the first mold such as to be in communication with the at least one first air suction line; and a vacuum pump configured to form at least a partial vacuum in the first vacuum holes, wherein the first adhesion support mechanism is configured to adhere the at least one substrate on the release film by suctioning air from the first vacuum holes through the through holes that are in communication with the at least one first air suction line. The molding apparatus may further include a second adhesion support mechanism that includes: second vacuum holes extending through the first mold such as to be opened through the seating surface of the first mold; and a second vacuum pump configured to form at least a partial vacuum in the second vacuum holes, wherein the second adhesion support mechanism is configured to adhere the release film on the seating surface.

According to example embodiments, a method of manufacturing a semiconductor package is provided. The method may include providing a lower mold having a seating surface on which at least one substrate is seated, the lower mold including: at least one substrate suction groove extending in at least one direction in the seating surface; first vacuum holes extending through the lower mold such as to be in communication with the at least one substrate suction groove; and second vacuum holes extending through the lower mold such as to be opened through the seating surface; supplying a release film on the seating surface of the lower mold, the release film including through holes therein, wherein the through holes of the release film disposed on the seating surface are in communication with the at least one substrate suction groove of the lower mold. The method may further include: adhering the release film on the seating surface of the lower mold by suctioning air from the second vacuum holes; disposing the at least one substrate on the release film on the seating surface; adhering the at least one substrate on the release film by suctioning air from the first vacuum holes through the through holes of the release film; clamping an upper mold with the lower mold to form a molding space that is configured to mold at least one semiconductor chip on the at least one substrate; and injecting a sealing material into the molding space to form a molding member covering the at least one semiconductor chip on the at least one substrate.

According to example embodiments, a molding apparatus for a semiconductor package may include: a release film supply mechanism configured to provides a release film having a plurality of through holes formed therein to be spaced apart in one direction, on a seating surface of a lower mold; a first adhesion support mechanism configured to adhere a substrate on the release film by suctioning air from first vacuum holes formed in the lower mold through the through holes of the release film; and a second adhesion support mechanism configured to adhere the release film on the seating surface by suctioning air from second vacuum holes formed in the lower mold to be opened through the seating surface.

According to examples embodiment, even when a mold member is formed on the substrate in a state in which the release film is interposed between the seating surface of the lower mold and the substrate, the substrate may be stably adhered and supported on the release film by the first adhesion support mechanism.

Thus, when the molding member is formed on the substrate within the mold, the substrate on the release film may be prevented from being bent or misaligned to prevent defects in a molded product, and by using the release film, a cleaning process of the mold may be omitted, to thereby improve production efficiency.

### BRIEF DESCRIPTION OF DRAWINGS

Example embodiments will be more clearly understood from the following detailed description taken in conjunction with the accompanying drawings. FIGS. 1 to 13 represent non-limiting, example embodiments as described herein.

FIG. 1 is a first cross-sectional view illustrating a molding apparatus for a semiconductor package in accordance with example embodiments.

FIG. 2 is a second cross-sectional view illustrating the molding apparatus for the semiconductor package in accordance with example embodiments.

FIG. 3 is a third cross-sectional view illustrating the molding apparatus for the semiconductor package in accordance with example embodiments.

FIG. 4 is a fourth cross-sectional view illustrating the molding apparatus for the semiconductor package in accordance with example embodiments.

FIG. 5 is a plan view illustrating a lower mold of the molding apparatus of FIGS. 1 to 4.

FIG. 6 is a first cross-sectional view illustrating a molding apparatus for a semiconductor package in accordance with example embodiments.

FIG. 7 is a second cross-sectional view illustrating the molding apparatus for the semiconductor package in accordance with example embodiments.

FIG. 8 is a plan view illustrating a lower mold of the molding apparatus of FIGS. 6 and 7.

FIG. 9 is a first view illustrating a method of manufacturing a semiconductor package in accordance with example embodiments.

FIG. 10A is a second view illustrating the method of manufacturing the semiconductor package in accordance with example embodiments.

FIG. 10B is a third view illustrating the method of manufacturing the semiconductor package in accordance with example embodiments.

FIG. 10C is a fourth view illustrating the method of manufacturing the semiconductor package in accordance with example embodiments.

FIG. 11A is a fifth view illustrating the method of manufacturing the semiconductor package in accordance with example embodiments.

FIG. 11B is a sixth view illustrating the method of manufacturing the semiconductor package in accordance with example embodiments.

FIG. 11C is a seventh view illustrating the method of manufacturing the semiconductor package in accordance with example embodiments.

FIG. 12A is an eighth view illustrating the method of manufacturing the semiconductor package in accordance with example embodiments.

FIG. 12B is a ninth view illustrating the method of manufacturing the semiconductor package in accordance with example embodiments.

FIG. 12C is a tenth view illustrating the method of manufacturing the semiconductor package in accordance with example embodiments.

FIG. 13 is an eleventh view illustrating the method of manufacturing the semiconductor package in accordance with example embodiments.

### DETAILED DESCRIPTION

Hereinafter, non-limiting example embodiments will be explained in detail with reference to the accompanying drawings.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

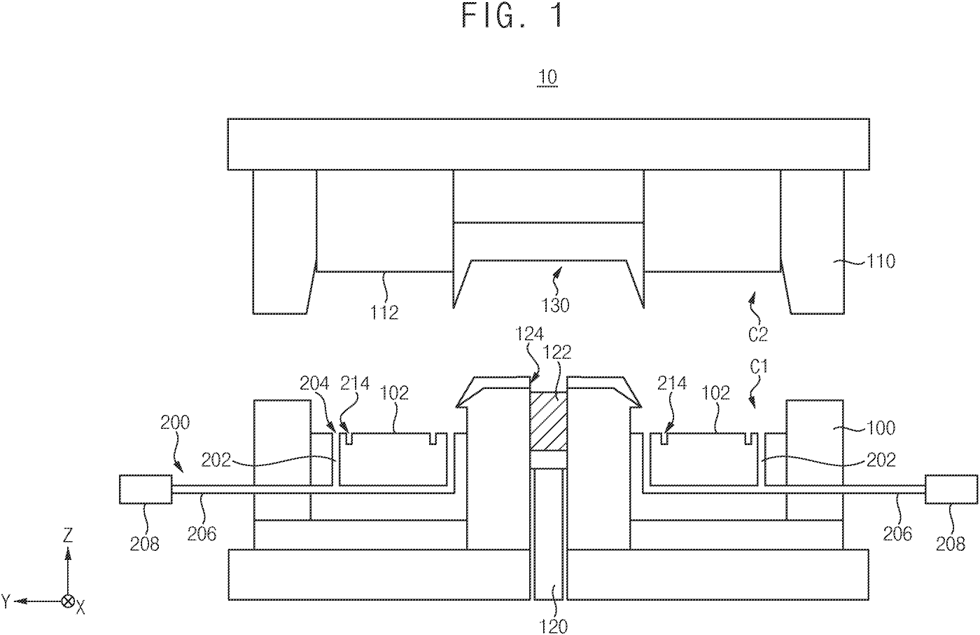

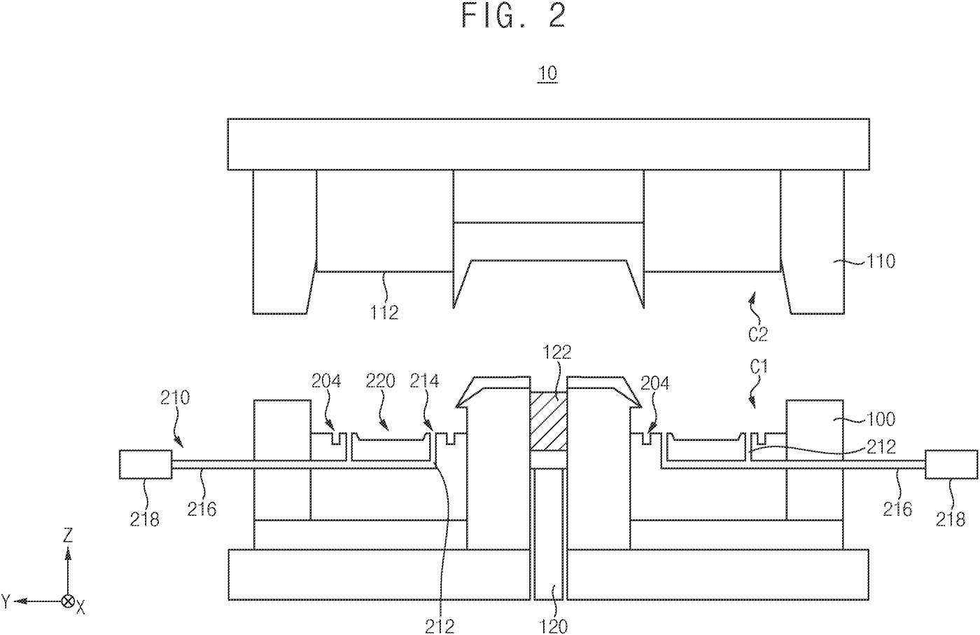

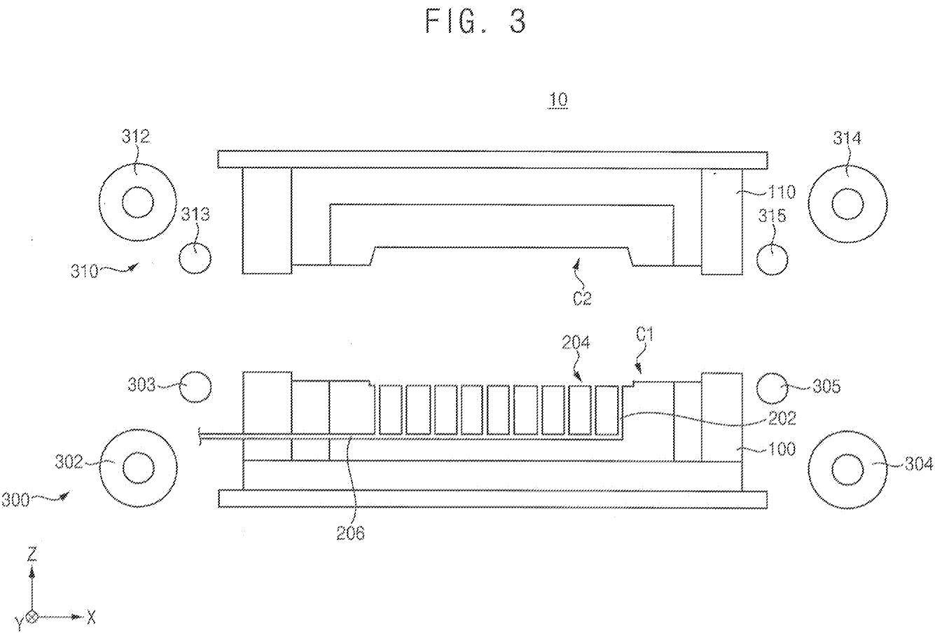

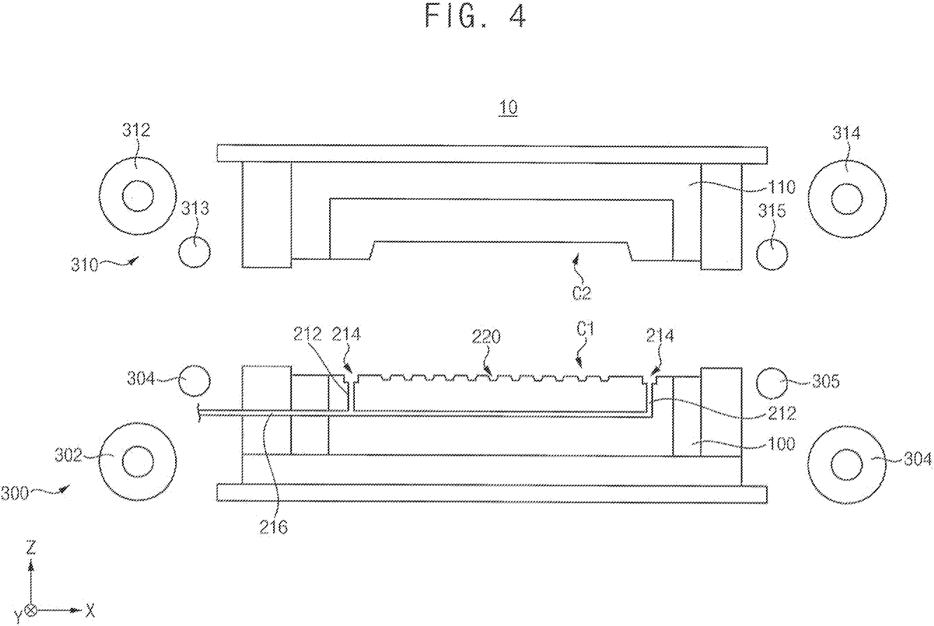

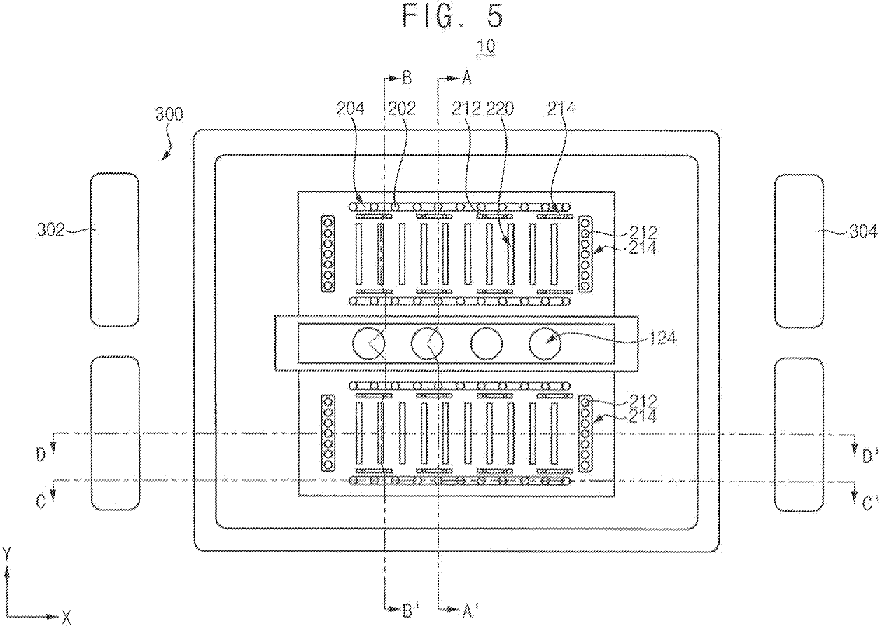

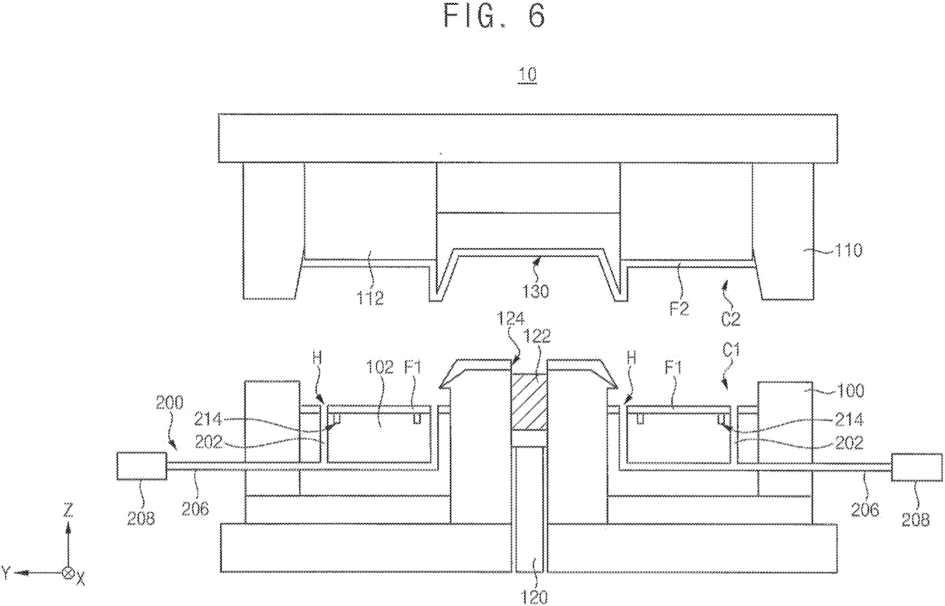

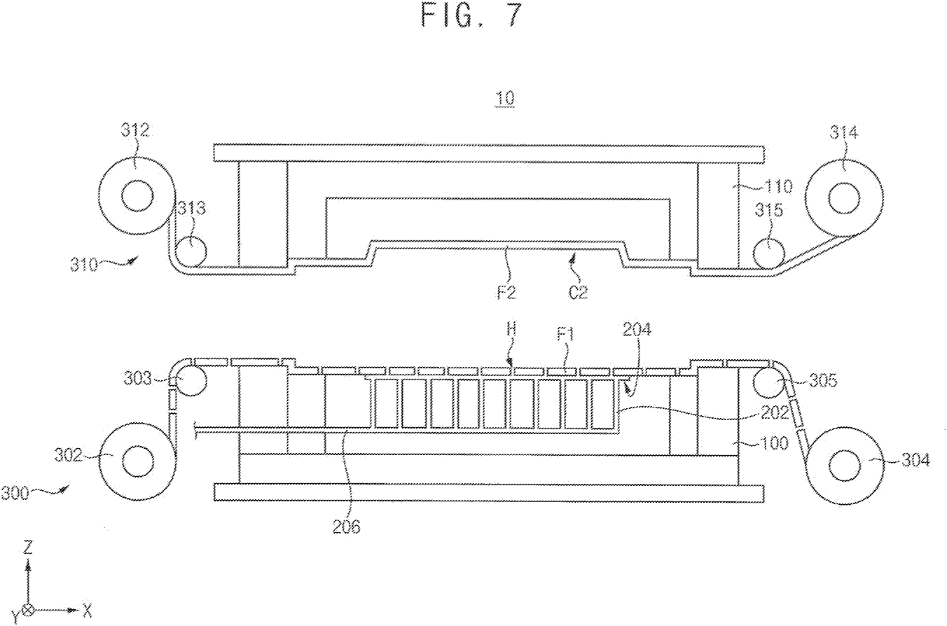

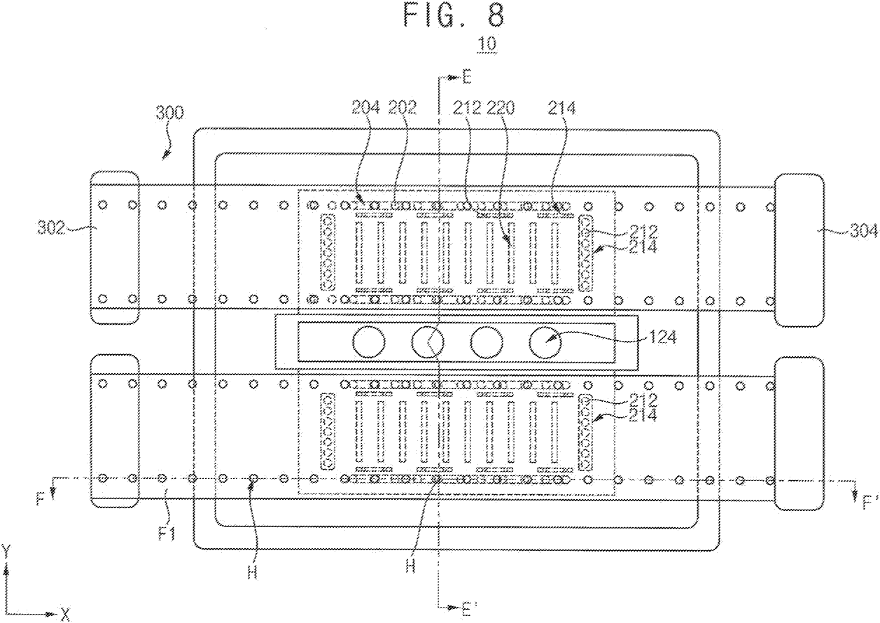

FIGS. 1 to 4 are cross-sectional views illustrating a molding apparatus for a semiconductor package in accordance with example embodiments. FIG. 5 is a plan view illustrating a lower mold of the molding apparatus of FIGS. 1 to 4. FIGS. 6 and 7 are cross-sectional views illustrating a molding apparatus for a semiconductor package in accordance with example embodiments. FIG. 8 is a plan view illustrating a lower mold of the molding apparatus of FIGS. 6 and 7. FIGS. 1 to 5 are views illustrating the molding apparatus before a release film is loaded onto the lower mold for convenience of explanation. FIG. 1 is a cross-sectional view taken along the line A-A′ in FIG. 5. FIG. 2 is a cross-sectional view taken along the line B—B′ in FIG. 5. FIG. 3 is a cross-sectional view taken along the line C—C′ in FIG. 5. FIG. 4 is a cross-sectional view taken along the line D-D′ in FIG. 5. FIG. 6 is a cross-sectional view taken along line the E-E′ in FIG. 8. FIG. 7 is a cross-sectional view taken along the line F—F′ in FIG. 8.

Referring to FIGS. 1 to 8, a molding apparatus 10 for a semiconductor package may include a mold having a lower mold 100 and an upper mold 110 that are clamped to each other to form a molding space for molding at least one semiconductor chip on a substrate therein. The molding apparatus 10 may be a transfer molding apparatus configured to injected and flow a liquid sealing material into the molding space to mold the semiconductor chip.

In example embodiments, in order to manufacture a semiconductor package, a plurality of semiconductor chips individualized from a wafer may be mounted on a strip-shaped substrate, and then may be loaded into the molding apparatus 10 to perform a molding process for protecting the semiconductor chips from the external environment. For example, tens to hundreds of semiconductor chips may be disposed on the substrate.

The molding apparatus 10 may perform a molded underfill (MUF) process. The substrate may be disposed in the molding space, and a sealing material 122 may flow at high temperature and high pressure while the lower mold 100 and the upper mold 110 are clamped so that the sealing material 122, that is liquid, flows inside the molding space and then solidifies to form a molding member covering the semiconductor chip. For example, the sealing material 122 may include an epoxy mold compound (EMC).

As illustrated in FIGS. 1 to 4, a first cavity C1 for accommodating the substrate onto which the semiconductor chip is bonded may be provided in an upper surface of the lower mold 100. A bottom surface of the first cavity C1 may include a seating surface 102 on which the substrate is seated. A second cavity C2 for forming the molding space together with the first cavity C1 may be provided in a lower surface of the upper mold 110. A bottom surface of the second cavity C2 may include a suction surface 112 facing the seating surface 102 of the lower mold 100. One of the lower mold 100 and the upper mold 110 may serve as a first mold on which the substrate is seated, and the other may serve as a second mold which is clamped with the first mold to form the molding space.

The molding space in the mold may include the first cavity C1 and the second cavity C2 in which the semiconductor chip on the substrate is disposed, and a curl 130 through which the sealing material 122 is supplied. Although not illustrated in the drawings, a plurality of gate runners which are paths for introducing the sealing material 122 from the curl into the first cavity C1 and the second cavity C2, a vent portion which exhausts a gas generated in the molding space as the sealing material 122 is introduced, etc. may be provided in the mold.

It will be understood that dimensions of each component in the molding space including the first cavity C1 and the second cavity C2 are examples, and may be determined in consideration of an area of the substrate, the number of the semiconductor chips, physical properties of the sealing material 122, etc.

The sealing material 122 may be a tablet-type from a sealing material supply (not illustrated) and may be disposed onto a plunger 120 and heated to have fluidity. Then, as the plunger 120 goes up, the sealing material 122, that is liquid, may flow into the molding space by the pressure of the plunger 120 and then may solidify to form the molding member on the substrate.

In example embodiments, the molding apparatus 10 may include a release film supply mechanism 300 configured to provide a release film F1 on the seating surface 102 of the lower mold 100, a first adhesion support mechanism 200 configured to adhere the substrate on the release film F1, and a second adhesion support mechanism 210 configured to adhere the release film F1 on the seating surface 102. In addition, the molding apparatus 10 may further include an upper release film supply mechanism 310 configured to provide an upper release film F2 on the suction surface 112 of the upper mold 110. Furthermore, the molding apparatus 10 may further include a third adhesion support mechanism configured to adhere the upper release film F2 on the suction surface 112 of the upper mold 110.

The first adhesion support mechanism 200 as a substrate adhesion mechanism may include at least one first air suction line 204 (e.g., substrate suction groove) extending in at least one direction in the seating surface 102 of the lower mold 100, a plurality of first vacuum holes 202 respectively formed to extend through the lower mold 100 and being in communication with the first air suction line 204, and a first vacuum pump 208 configured to form at least a partial vacuum in each of the first vacuum holes 202.

The second adhesion support mechanism 210 as a film adhesion mechanism may include a plurality of second vacuum holes 212 respectively formed to extend through the lower mold 100 so as to be opened through the seating surface 102 of the lower mold 100, and a second vacuum pump 218 configured to form at least a partial vacuum in each of the second vacuum holes 212. In addition, the second adhesion support mechanism 210 may further include at least one second air suction line 214 (e.g., film suction groove) extending in at least one direction in the seating surface 102 of the lower mold 100. The second vacuum holes 212 may be in communication with the second air suction line 214, respectively.

As illustrated in FIG. 5, the first air suction line 204 may extend by a predetermined length in a first direction (X direction). The first air suction line 204 may have a recess shape having a predetermined depth from the seating surface 102. The first vacuum holes 202 may extend in a vertical direction (Z direction) from a bottom surface of the first air suction line 204. The first air suction line 204 may be a substrate suction groove extending in one direction to connect upper end portions of the first vacuum holes 202 to each other. For example, several to tens of the first vacuum holes 202 may be in communication with the first air suction line 204, respectively. Two of the first air suction lins 204 may extend along both sides of the seating surface 102, respectively. A diameter of each of the first vacuum holes 202 may be within a range of 0.5 mm to 1.5 mm. The depth of the first air suction line 204 may be within a range of 0.5 mm to 1.5 mm.

The second air suction line 214 may extend by a predetermined length in the first direction (X direction). The second air suction line 214 may have a recess shape having a predetermined depth from the seating surface 102. The second vacuum holes 212 may extend in the vertical direction (Z direction) from a bottom surface of the second air suction line 214. The second air suction line 214 may be a film suction groove extending in one direction to connect upper end portions of the second vacuum holes 212 to each other. For example, two second vacuum holes 212 may be in communication with one second air suction line 214. Alternatively, one of the second vacuum holes 212 may be in communication with one second air suction line 214. Four of the second air suction line 214 may be arranged to be spaced apart from each other along one side of the seating surface 102. The four of the second air suction line 214 may be arranged adjacent to the first air suction line 204. The four of the second air suction line 214 may be located more inward than the first air suction line 204. A diameter of each of the second vacuum holes may be within a range of 0.5 mm to 2.5 mm. The depth of the second air suction line 214 may be in a range of 0.5 mm to 2.5 mm.

The second air suction line 214 may extend by a predetermined length in a second direction (Y direction) perpendicular to the first direction (X direction). For example, two of the second air suction line 214 may each extend in the second direction (Y direction) along both sides of the seating surface 102. The length of the first air suction line 204 may be greater than the length of the second air suction line 214.

In example embodiments, the lower mold 100 may further include at least one sealing material accommodating line 220 extending in the seating surface 102 in at least one direction. The sealing material accommodating line 220 may be provided to correspond to at least one sealing material passage hole formed to penetrate through the substrate, as will be described later.

For example, the sealing material accommodating line 220 may extend by a predetermined length in the second direction (Y direction). The sealing material accommodating line 220 may have a recess shape having a predetermined depth from the seating surface 102. A plurality of the sealing material accommodating line 220 may be arranged to be spaced apart from each other in the first direction (X direction). A plurality of the sealing material accommodating line 220 may be arranged in a central region of the seating surface 102.

With reference to FIGS. 6 to 8, the release film supply mechanism 300 may supply the release film F1 in the first direction (X direction). The release film supply mechanism 300 may include a feeding roller 302 and a winding roller 304 respectively disposed on both sides of the lower mold 100. The release film F1 may be loaded onto the seating surface 102 of the lower mold 100 from the feeding roller 302 as it is wound by the winding roller 304.

The release film F1 may include a material having heat resistance, non-adhesiveness, and ductility. For example, the release film may include a resin such as polyethylene terephthalate (PET) or polytetrafluoroethylene (PTFE) (Teflon). Accordingly, after the molding member is formed on the substrate while the release film F1 is interposed between the seating surface 102 and the substrate, the substrate on which the molding member is formed may be easily removed from the seating surface 102 by the release film F1 to prevent the molding member formed on a lower surface of the substrate from sticking to the lower mold 100.

A plurality of through holes H may be formed in the release film F1. When the first air suction line 204 extends in the first direction (X direction), the through holes H of the release film F1 that is supplied in the first direction may be arranged to be spaced apart from each other in the first direction (X direction). When the release film F1 is disposed on the seating surface 102 of the lower mold 100, at least some of the through holes H may be arranged to be in communication with the first air suction line 204. In this case, a spacing distance between the first vacuum holes 202 in communication with the first air suction line 204 may be smaller than a spacing distance between the through holes H. For example, a diameter of each of the through holes H may be within a range of 0.5 mm to 1.5 mm. The spacing distance between the first vacuum holes 202 may be within a range of 10 mm to 20 mm. The spacing distance between the through holes H may be within a range of 20 mm to 30 mm.

In example embodiments, the first vacuum pump 208 may be in communication with the first vacuum holes 202 by a first exhaust line 206 to form at least a partial vacuum in the first vacuum holes 202. When the first vacuum pump 208 suctions air from the first vacuum holes 202, the air may be suctioned through the first air suction line 204 in communication with the first vacuum holes 202. Accordingly, the substrate may be adhered and supported on the release film F1 by the at least a partial vacuum formed in the through holes H.

The second vacuum pump 218 may be in communication with the second vacuum holes 212 by a second exhaust line 216 to form at least a partial vacuum in the second vacuum holes 212. When the second vacuum pump 218 suctions air from the second vacuum holes 212, the air may be suctioned through the second air suction line 214 in communication with the second vacuum holes 212. Accordingly, the release film F1 may be adhered and supported on the seating surface 102 by the at least a partial vacuum formed in the second air suction line 214.

In example embodiments, the upper release film supply mechanism 310 may supply the upper release film F2 in the first direction (X direction). The upper release film supply mechanism 310 may include an upper feeding roller 312 and an upper winding roller 314 respectively disposed on both sides of the upper mold 110. The upper release film F2 may be loaded onto the suction surface 112 of the upper mold 110 from the upper feeding roller 312 as it is wound by the upper winding roller 314.

Similar to the second adhesion support mechanism 210, the third adhesion support mechanism as an upper film adhesion mechanism may include a plurality of third vacuum holes (not illustrated) respectively formed to extend through the upper mold 110 so as to be opened through the suction surface 112 of the upper mold 110 and a third vacuum pump (not illustrated) configured to form at least a partial vacuum in each of the third vacuum holes. In addition, the third adhesion support mechanism may further include at least one third air suction line (e.g., upper film suction groove) extending in at least one direction in the suction surface 112 of the upper mold 110. The third vacuum holes may be in communication with the third air suction line, respectively.

The third vacuum pump may be in communication with the third vacuum holes by a third exhaust line (not illustrated) to form at least a partial vacuum in the third vacuum holes. When the third vacuum pump suctions air from the third vacuum holes, the air may be suctioned through the third air suction line in communication with the third vacuum holes. Accordingly, the upper release film F2 may be adhered and supported on the suction surface 112 of the upper mold 110 by the at least a partial vacuum formed in the third air suction line.

As mentioned above, the molding apparatus 10 for the semiconductor package may include the release film supply mechanism 300 configured to provides the release film F1 having a plurality of the through holes H formed therein to be spaced apart in one direction on the seating surface 102 of the lower mold 100, the first adhesion support mechanism 200 configured to adhere the substrate on the release film F1 by suctioning air from the first vacuum holes 202 formed in the lower mold 100 through the through holes H of the release film F1, and the second adhesion support mechanism 210 configured to adhere the release film F1 on the seating surface 102 by suctioning air from the second vacuum holes 212 formed in the lower mold 100 to be opened through the seating surface 102.

Accordingly, even when the mold member is formed on the substrate in a state in which the release film F1 is interposed between the seating surface 102 of the lower mold 100 and the substrate, the substrate may be stably adhered and supported on the release film F1 by the first adhesion support mechanism 200.

Thus, when the molding member is formed on the substrate within the mold, the substrate on the release film F1 may be prevented from being bent or misaligned to prevent defects in the molded product, and by using the release film F1, a cleaning process of the mold may be omitted, to thereby improve production efficiency.

Hereinafter, a method of manufacturing a semiconductor package using the molding apparatus for a semiconductor package will be described.

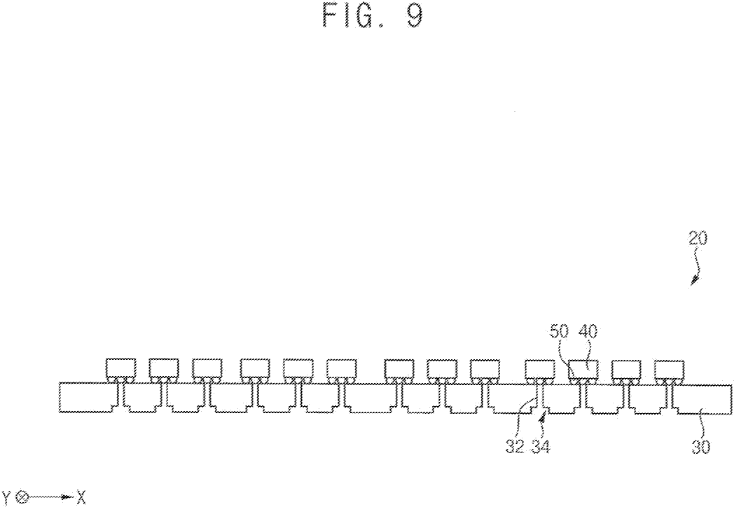

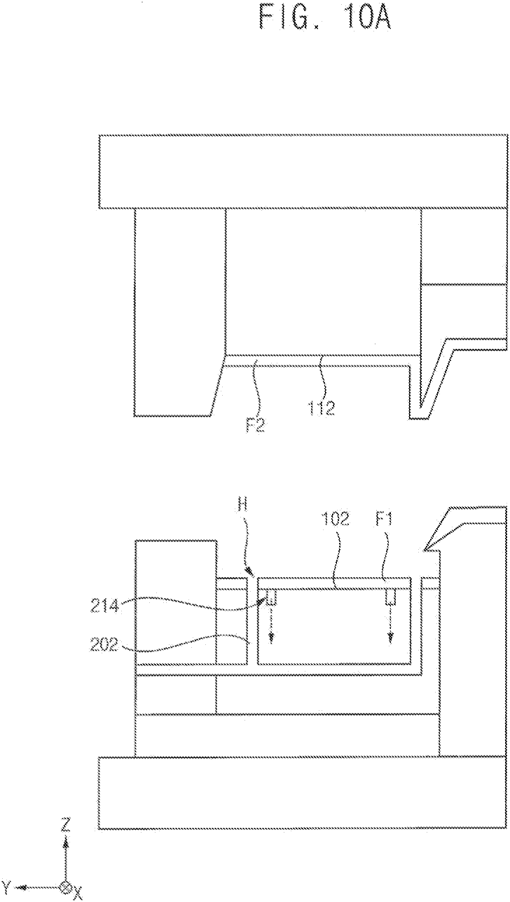

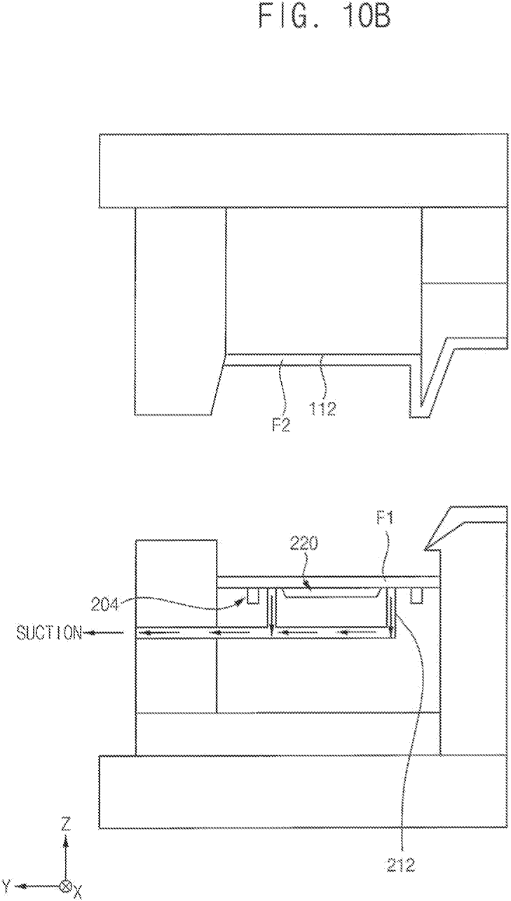

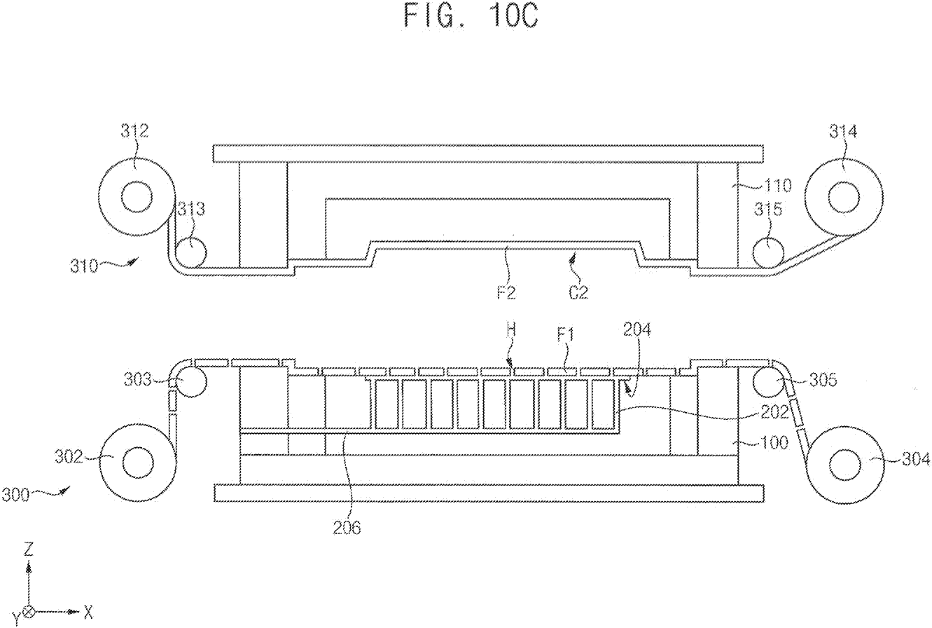

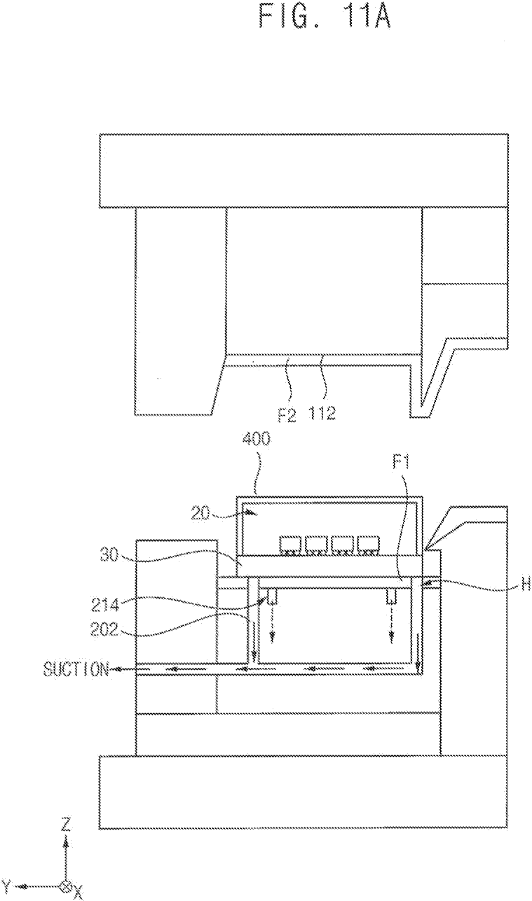

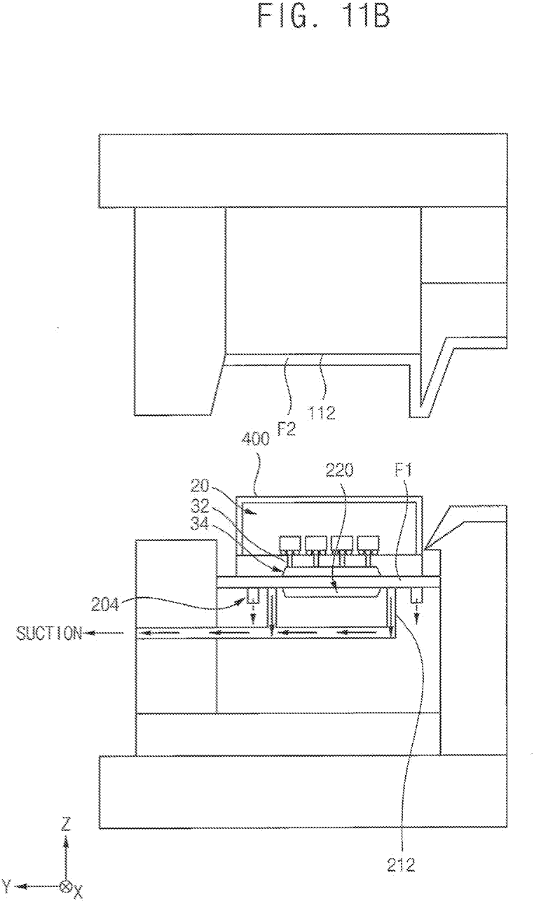

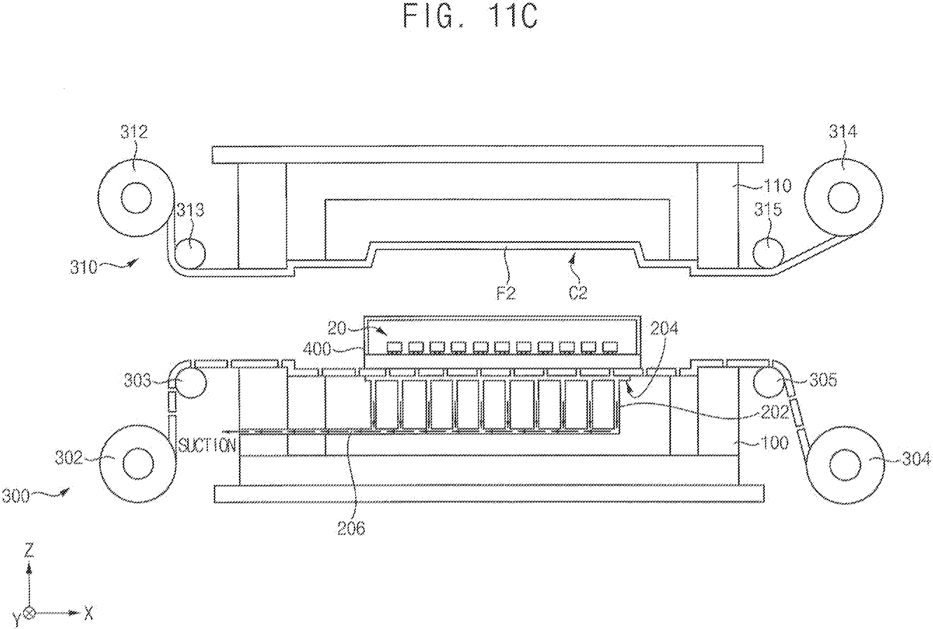

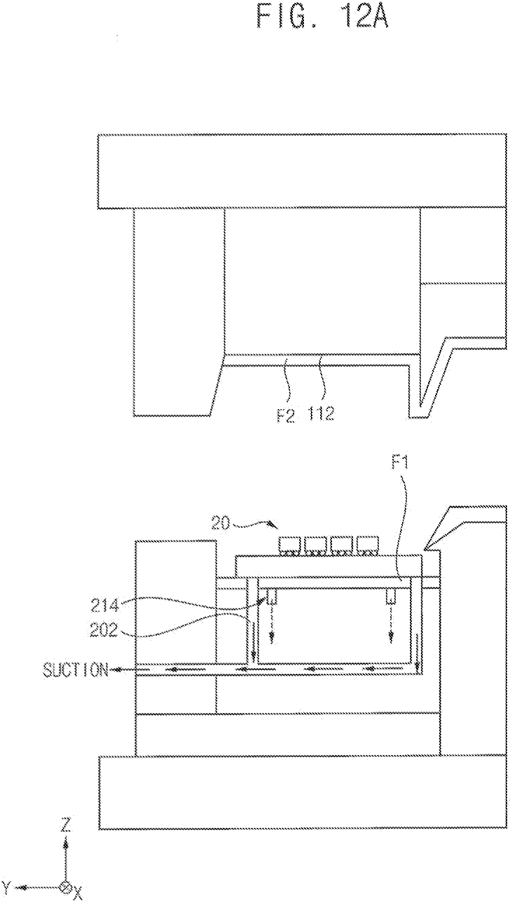

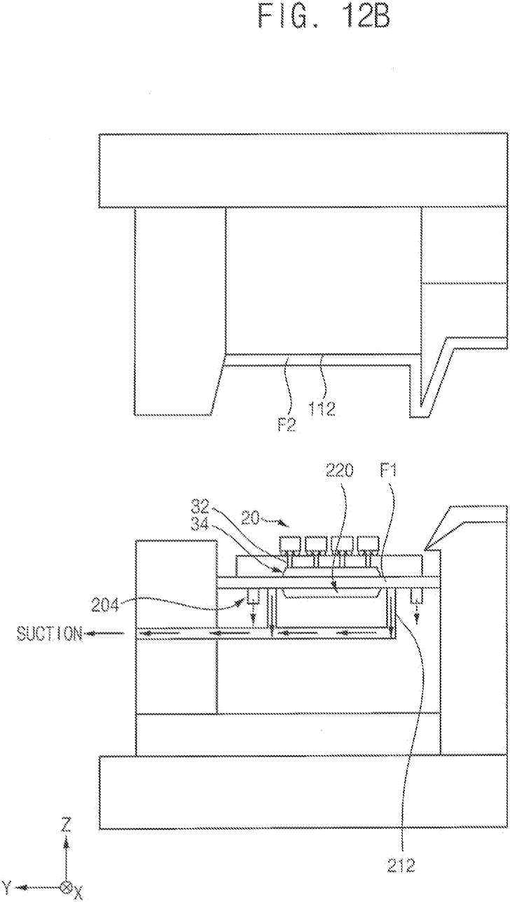

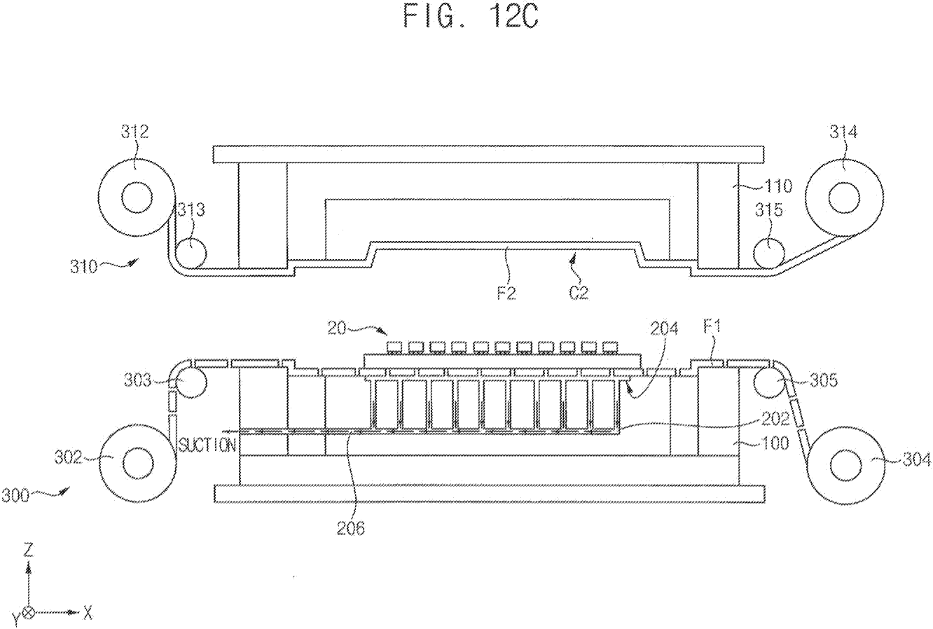

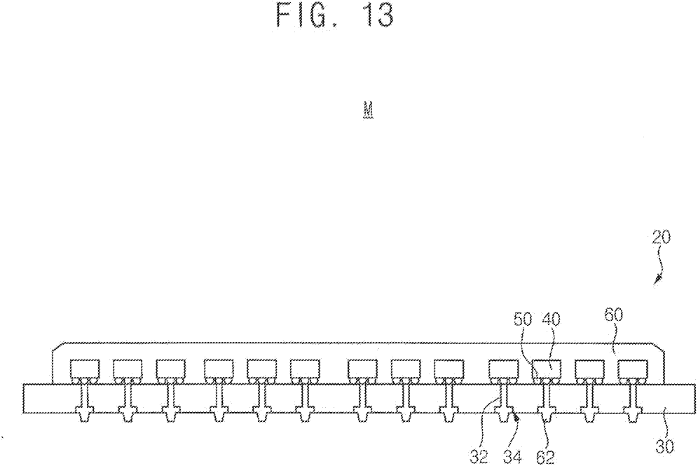

FIGS. 9 to 13 are views illustrating a method of manufacturing a semiconductor package in accordance with example embodiments. FIG. 9 is a plan view illustrating a substrate on which semiconductor chips are mounted. FIGS. 10A to 10C are cross-sectional views illustrating a stage of providing a release film and an upper release film. FIGS. 11A to 11C are cross-sectional views illustrating a stage of loading a substrate on a seating surface of a lower mold. FIGS. 12A to 12C are cross-sectional views illustrating a stage of adhering and supporting the substrate. FIG. 13 is a cross-sectional view illustrating a resin molded article including a molding member formed on the substrate by the molding apparatus of FIG. 1.

Referring to FIG. 9, first, a plurality of semiconductor chips 40 may be mounted on a substrate 30 to form a semiconductor strip substrate 20.

In example embodiments, in order to manufacture a semiconductor package, a plurality of the semiconductor chips 40 individualized from a wafer may be mounted on the substrate 30, and then, a molding process for protecting the semiconductor chips 40 from an external environment may be performed.

For example, the substrate 30 may be a multi-layer circuit board as a package substrate having upper and lower surfaces facing away from each other. The substrate 30 may be a strip substrate for manufacturing a semiconductor strip, such as a printed circuit board (PCB).

The substrate 30 may include a plurality of chip mounting regions for mounting the plurality of semiconductor chips 40, and the semiconductor chips 40 may be respectively disposed on the chip mounting regions. For example, tens to hundreds of the semiconductor chips 40 may be arranged on the substrate 30 in a matrix form.

The substrate 30 may have at least one sealing material passage hole 32 in the chip mounting region. The sealing material passage hole 32 may be formed to penetrate through the substrate 30. A plurality of the sealing material passage hole 32 may be spaced apart from each other in the second direction (Y direction) in one chip mounting area.

Additionally, the substrate 30 may have a sealing material receiving groove 34 formed in a groove shape in a lower surface of the substrate 30 to connect a plurality of the sealing material passage hole 32 to each other. A plurality of the sealing material receiving groove 34 may be spaced apart from each other in the first direction (X direction). The sealing material receiving groove 34 may extend by a predetermined length in the second direction (Y direction) perpendicular to the first direction to connect a plurality of the sealing material passage hole 32 in one chip mounting region with each other.

After conductive bumps 50 are formed on chip pads on the lower surface of at least one of the semiconductor chips 40, a plurality of the semiconductor chips 40 may be placed in a matrix array on the substrate 30 via the conductive bumps 50. In this case, the conductive bumps 50 may be respectively disposed on substrate pads on the substrate 30. Then, the conductive bumps 50 may be attached to the substrate pads by a reflow process to mount the semiconductor chips 40 on the substrate 30.

Referring to FIGS. 10A to 10C, a release film F1 having a plurality of through holes H may be supplied on a seating surface 102 of a lower mold 100. In addition, an upper release film F2 may be supplied on a suction surface 112 of an upper mold 110.

In example embodiments, a release film supply mechanism 300 may supply the release film F1 on the seating surface 102 of the lower mold 100 in the first direction (X direction). A plurality of the through holes H may be formed in the release film F1. A first air suction line 204 may extend in the first direction (X direction). When the release film F1 is disposed on the seating surface 102 of the lower mold 100, at least some of the through holes H may be arranged on the first air suction line 204 to be in communication with the first air suction line 204.

An upper release film supply mechanism 310 may supply the upper release film F2 on the suction surface 112 of the upper mold 110 in the first direction (X direction).

Then, the release film F1 may be adhered on the seating surface 102 of the lower mold 100 by suctioning air from second vacuum holes 212. In addition, the upper release film F2 may be adhered on the suction surface 112 of the upper mold 110.

A second vacuum pump 218 (refer to FIG. 2) may be in communication with the second vacuum holes 212 by a second exhaust line 216 to form at least a partial vacuum in the second vacuum holes 212. When the second vacuum pump 218 suctions the air from the second vacuum holes 212, the air may be suctioned through the second air suction line 214 in communication with the second vacuum holes 212. Accordingly, the release film F1 may be adhered and supported on the seating surface 102 by the at least a partial vacuum formed in the second air suction line 214.

Similarly, a third vacuum pump (not illustrated) may be in communication with third vacuum holes formed in the upper mold 110 by a third exhaust line to form at least a partial vacuum in the third vacuum holes. When the third vacuum pump suctions air from the third vacuum holes, the air may be suctioned through a third air suction line formed in the suction surface 112 to be in communication with the third vacuum holes. Accordingly, the upper release film F2 may be adhered and supported on the suction surface 112 of the upper mold 110 by the at least a partial vacuum formed in the third air suction line.

Referring to FIGS. 11A to 11C, the semiconductor strip substrate 20 may be disposed on the release film F1 on the seating surface 102, and the semiconductor strip substrate 20 may be adhered on the release film F1 by suctioning air from first vacuum holes 202 through the through holes H of the release film F1.

In example embodiments, the semiconductor strip substrate 20 may be loaded onto the release film F1 on the seating surface 102 using a substrate handler 400. Then, the substrate 30 may be adhered on the release film F1 by suctioning air from the first vacuum holes 202. At this time, the release film F1 may be adhered and supported on the seating surface 102 by the at least a partial vacuum formed in the second air suction line 214.

A first vacuum pump 208 (refer to FIGS. 1 and 6) may be in communication with the first vacuum holes 202 by a first exhaust line 206 to form at least a partial vacuum in the first vacuum holes 202. When the first vacuum pump 208 suctions air from the first vacuum holes 202, the air may be suctioned through a first air suction line 204 in communication with the first vacuum holes 202 and the through holes H of the release film F1 in communication with the first air suction line 204. Accordingly, the substrate may be adhered and supported on the release film F1 by the at least a partial vacuum formed in the through holes H.

When the substrate 30 is disposed on the release film F1 on the seating surface 102, the at least one sealing material passage hole 32 formed in the substrate 30 may be disposed to correspond to a sealing material accommodating line 220 formed in the seating surface 102 of the lower mold 100. The plurality of the sealing material receiving groove 34 formed in the lower surface of the substrate 30 may be disposed to overlap the plurality of the sealing material accommodating line 220 formed in the seating surface 102, respectively.

Referring to FIGS. 12A to 13, the substrate handler 400 may be returned, and a sealing material may flow at high temperature and high pressure while the lower mold 100 and the upper mold 110 are clamped so that the liquid sealing material flows in the molding space and then solidifies to form a molding member 60 covering the semiconductor chips 40. For example, the sealing material may include an epoxy mold compound (EMC).

The molded article M for a semiconductor strip may include the molding member 60 formed on the substrate 30. The molding member 60 may be a portion of a resin in which the liquid resin is solidified in the first cavity C1 and the second cavity C2 (refer to FIGS. 1, 2, 4, and 6) of the molding space to cover the plurality of semiconductor chips 40 on the substrate 30.

When the sealing material is injected into the first cavity C1 and the second cavity C2, it may flow into the sealing material passage hole 32 and the sealing material receiving groove 34 and then may be solidified to form a sealing material lower pattern 62 on the lower surface of the substrate 30. As such, when performing the molded underfill (MUF) process, the sealing material between an upper surface of the substrate 30 and at least one of the semiconductor chips 40 may fill the sealing material receiving groove 34 through the sealing material passage hole 32. At this time, the sealing material receiving groove 34 may be a passage through which air inside the first cavity C1 and the second cavity C2 exits to the outside.

Then, after the mold resin is cured for a predetermined time, the substrate 30 may be individually divided to manufacture a plurality of flip-chip semiconductor packages.

The manufacturing method for the semiconductor package may be used for manufacturing a semiconductor package including semiconductor devices such as logic devices or memory devices. The semiconductor package may include logic devices such as central processing units (CPUs), main processing units (MPUs), or application processors (APs), or the like, and volatile memory devices such as DRAM devices, HBM devices, or non-volatile memory devices such as flash memory devices, PRAM devices, MRAM devices, ReRAM devices, or the like.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages of embodiments of the present disclosure. Accordingly, all such modifications are intended to be included within the scope of example embodiments of the present disclosure.

What is claimed is:

1. A molding apparatus for a semiconductor package, comprising:
a lower mold comprising:
a seating surface on which at least one substrate is configured to be seated;
at least one substrate suction groove extending in at least one direction in the seating surface of the lower mold;
first vacuum holes extending through the lower mold such as to be in communication with the at least one substrate suction groove and in which at least a partial vacuum is configured to be formed; and
second vacuum holes extending through the lower mold such as to be opened through the seating surface and in which at least a partial vacuum is configured to be formed;
an upper mold positioned above the lower mold and configured to be clamped with the lower mold to form a molding space configured to mold at least one semiconductor chip on the at least one substrate; and
a release film supply mechanism configured to supply a release film on the seating surface of the lower mold, the release film having through holes therein, wherein the through holes of the release film disposed on the seating surface are configured to be in communication with the at least one substrate suction groove,
wherein the release film is configured to be adhered on the seating surface by suctioning air from the second vacuum holes, and
wherein the at least one substrate is configured to be adhered on the release film by suctioning air from the first vacuum holes through the through holes of the release film.

2. The molding apparatus of claim 1, wherein the lower mold further comprises:
at least one film suction groove extending in at least one direction in the seating surface of the lower mold, the at least one film suction groove being in communication with at least one of the second vacuum holes.

3. The molding apparatus of claim 2, wherein a length of the at least one substrate suction groove is greater than a length of the at least one film suction groove.

4. The molding apparatus of claim 2, wherein the at least one film suction groove is located more inward than the at least one substrate suction groove with respect to the seating surface of the lower mold.

5. The molding apparatus of claim 1, wherein the at least one substrate suction groove extends in a first direction, and the through holes are spaced apart from each other in the first direction.

6. The molding apparatus of claim 5, wherein the release film supply mechanism comprises a feeding roller and a winding roller disposed on respective sides of the lower mold to supply the release film in the first direction.

7. The molding apparatus of claim 1, further comprising:
an upper release film supply mechanism configured to supply an upper release film on a suction surface of the upper mold facing the seating surface.

8. The molding apparatus of claim 1, wherein the at least one substrate comprises at least one sealing material passage hole that extends in one or more directions and penetrates through the at least one substrate, and
wherein the lower mold further comprises at least one sealing material accommodating line that extends in the seating surface to correspond to the at least one sealing material passage hole.

9. The molding apparatus of claim 1, further comprising:
a first vacuum pump configured to form the at least the partial vacuum in the first vacuum holes; and
a second vacuum pump configured to form the at least the partial vacuum in the second vacuum holes.

10. The molding apparatus of claim 1, wherein a spacing distance between the first vacuum holes is smaller than a spacing distance between the through holes.

11. A molding apparatus for a semiconductor package, comprising:
a first mold comprising a seating surface on which at least one substrate is configured to be seated;
a second mold facing the first mold and configured to be clamped with the first mold to form a molding space configured to mold at least one semiconductor chip on the at least one substrate;
a release film supply mechanism configured to supply a release film on the seating surface of the first mold in a first direction, the release film having through holes that are spaced apart in the first direction;
a first adhesion support mechanism comprising:
at least one first air suction line extending in the first direction in the seating surface of the first mold;
first vacuum holes extending through the first mold such as to be in communication with the at least one first air suction line; and
a vacuum pump configured to form at least a partial vacuum in the first vacuum holes, wherein the first adhesion support mechanism is configured to adhere the at least one substrate on the release film by suctioning air from the first vacuum holes through the through holes that are in communication with the at least one first air suction line; and
a second adhesion support mechanism comprising:
second vacuum holes extending through the first mold such as to be opened through the seating surface of the first mold; and
a second vacuum pump configured to form at least a partial vacuum in the second vacuum holes, wherein the second adhesion support mechanism is configured to adhere the release film on the seating surface.

12. The molding apparatus of claim 11, wherein the second adhesion support mechanism further comprises at least one second air suction line extending in the seating surface of the first mold, the at least one second air suction line being in communication with at least one of the second vacuum holes.

13. The molding apparatus of claim 11, wherein the release film supply mechanism comprises a feeding roller and a winding roller disposed on respective sides of the first mold to supply the release film in the first direction.

14. The molding apparatus of claim 11, further comprising:
an upper release film supply mechanism configured to supply a second release film on a suction surface of the second mold facing the seating surface.

15. The molding apparatus of claim 11, wherein the at least one substrate comprises at least one sealing material passage hole that extends in at least one direction and penetrates through the at least one substrate, and
wherein the first mold further comprises at least one sealing material accommodating line that extends in the seating surface to correspond to the at least one sealing material passage hole.

16. A method of manufacturing a semiconductor package, the method comprising:
providing a lower mold having a seating surface on which at least one substrate is seated, the lower mold including:
at least one substrate suction groove extending in at least one direction in the seating surface;
first vacuum holes extending through the lower mold such as to be in communication with the at least one substrate suction groove; and
second vacuum holes extending through the lower mold such as to be opened through the seating surface;
supplying a release film on the seating surface of the lower mold, the release film including through holes therein, wherein the through holes of the release film disposed on the seating surface are in communication with the at least one substrate suction groove of the lower mold;
adhering the release film on the seating surface of the lower mold by suctioning air from the second vacuum holes;
disposing the at least one substrate on the release film on the seating surface;
adhering the at least one substrate on the release film by suctioning air from the first vacuum holes through the through holes of the release film;
clamping an upper mold with the lower mold to form a molding space that is configured to mold at least one semiconductor chip on the at least one substrate; and
injecting a sealing material into the molding space to form a molding member covering the at least one semiconductor chip on the at least one substrate.

17. The method of claim 16, wherein the supplying the release film comprises supplying the release film in a first direction from a feeding roller disposed on a first side of the lower mold to a winding roller disposed on a second side of the lower mold, opposite to the first side.

18. The method of claim 17, wherein the at least one substrate suction groove extends in the first direction, and the through holes are spaced apart from each other in the first direction.

19. The method of claim 16, wherein the at least one substrate includes at least one sealing material passage hole that extends in one or more directions and penetrates through the at least one substrate, and
wherein the lower mold further includes at least one sealing material accommodating line that extends in the seating surface in to correspond to the at least one sealing material passage hole.

20. The method of claim 16, further comprising supplying an upper release film on a
suction surface of the upper mold facing the seating surface of the lower mold.
